(19) United States
(12) Patent Application Publication
(10) Pub. No.: US 2013/0025669 A1
(43) Pub. Date: Jan. 31, 2013

(54) PHOTOVOLTAIC CELL SUBSTRATE, METHOD OF PRODUCING PHOTOVOLTAIC CELL SUBSTRATE, PHOTOVOLTAIC CELL ELEMENT AND PHOTOVOLTAIC CELL

(71) Applicants: Tetsuya SATO, Tsukuba-shi (JP); Masato Yoshida, Tsukuba-shi (JP); Takeshi Nojiri, Tsukuba-shi (JP); Youichi Machii, Tsukuba-shi (JP); Mitsunori Iwamuro, Tsukuba-shi (JP); Akihiro Orita, Tsukuba-shi (JP)

(72) Inventors: Tetsuya SATO, Tsukuba-shi (JP); Masato Yoshida, Tsukuba-shi (JP); Takeshi Nojiri, Tsukuba-shi (JP); Youichi Machii, Tsukuba-shi (JP); Mitsunori Iwamuro, Tsukuba-shi (JP); Akihiro Orita, Tsukuba-shi (JP)

(73) Assignee: HITACHI CHEMICAL COMPANY, LTD.

(21) Appl. No.: 13/556,850

(22) Filed: Jul. 24, 2012

Related U.S. Application Data
(60) Provisional application No. 61/511,236, filed on Jul. 25, 2011.

(30) Foreign Application Priority Data
Jul. 25, 2011 (JP) 2011-162610

(51) Int. Cl. H01L 31/0236; H01L 31/18; H01L 31/0224

(52) U.S. Cl. 136/256; 438/57; 257/E31.13

(57) ABSTRACT

The invention provides a photovoltaic cell substrate that is a semiconductor substrate comprising an n-type diffusion layer, an n⁺-type diffusion layer having a higher n-type impurity concentration than the n-type diffusion layer, and a concave portion at a surface of the n⁺-type diffusion layer.

### CROSS-REFERENCE TO RELATED APPLICATION

This application claims priority under 35 USC 119(e) from U.S. Provisional Application No. 61/511,236, the disclosure of which is incorporated by reference herein.

### BACKGROUND OF THE INVENTION

1. Field of the Invention

The present invention relates to a photovoltaic cell substrate, a method of producing a photovoltaic substrate, a photovoltaic cell element and a photovoltaic cell.

2. Related Art

In the production of a conventional photovoltaic cell having a pn junction, the pn junction is formed by, for example, forming an n-type diffusion layer by diffusing an n-type impurity into a p-type semiconductor substrate of silicon or the like.

In particular, as a structure of a photovoltaic cell that is configured to enhance the conversion efficiency, a selective emitter structure, in which the impurity concentration of a diffusion layer in a region other than a region right under an electrode (also referred to as a “light-receiving region”) is lower than the impurity concentration of a diffusion layer in a region right under an electrode, has been known (see, for example, L. Debarge, M. Schott, J. C. Muller and R. Monna, Solar Energy Materials & Solar Cells 74 (2002)71-75). In this structure, recombination of carriers is suppressed by decreasing the impurity concentration in a light-receiving region. On the other hand, contact resistance of a metal electrode and silicon is reduced by forming a region having a high impurity concentration right under the electrode. As a result, the conversion efficiency of the photovoltaic cell can be improved.

In order to form a selective emitter structure as described above, a method of forming a diffusion layer having a high impurity concentration only in a region right under an electrode using a mask (see, for example, Japanese Patent Application Laid-Open (JP-A) No. 2004-193350) and a method of forming a diffusion layer by applying a liquid having a high impurity concentration onto a region right under an electrode (see, for example, JP-A No. 2004-221149) have been proposed.

### SUMMARY OF THE INVENTION

### Problems to be Solved by the Invention

According to the conventional methods of forming a selective emitter layer as described above, it is known that sheet resistance at a surface of a substrate can be lowered to approximately 40Ω/□, which enables a favorable ohmic contact with an electrode, and that a diffusion region having a high impurity concentration can be formed.

However, in a process of forming an electrode for a light-receiving surface on the diffusion layer, it is difficult to distinguish a region having a high impurity concentration from the neighboring regions, and an electrode may not be properly formed on the region having a higher impurity concentration. Therefore, the electrode may contact the light-receiving region having a low impurity concentration, whereby contact resistance may be increased. In order to address this problem, the position of the diffusion region having a high impurity concentration and the position of an electrode are adjusted during printing of a paste for forming an electrode by marking the wafer for an alignment system controlled by a CCD camera. However, even in such a method, a slight difference in alignment may cause a significant mislocation especially in a case of forming a finger electrode whose width is approximately 100 μm.

In view of the circumstances as set forth above, the invention aims to provide a photovoltaic cell substrate that suppresses mislocation of an electrode with respect to an n⁺-type diffusion layer that has a high n-type impurity concentration and is positioned right under the electrode, in a photovoltaic cell having a selective emitter structure. The invention also aims to provide a method of producing the photovoltaic cell substrate, a photovoltaic cell element and a photovoltaic cell.

### Means for Solving the Problems

The following are embodiments of the invention for solving the problems.

<1> A photovoltaic cell substrate that is a semiconductor substrate comprising an n-type diffusion layer, an n⁺-type diffusion layer having a higher n-type impurity concentration than the n-type diffusion layer, and a concave portion at a surface of the n⁺-type diffusion layer.

<2> The photovoltaic cell substrate according to <1>, wherein the surface of the n⁺-type diffusion layer has a center line average roughness Ra of from 0.004 μm to 0.100 μm.

<3> The photovoltaic cell substrate according to <1> or <2>, wherein the n⁺-type diffusion layer comprises a region having an n-type impurity concentration of from 10¹² atoms/cm³ or more in at least a portion at a range of from 0.10 μm to 1.00 μm in depth from the surface of the n⁺-type diffusion layer.

<4> The photovoltaic cell substrate according to any one of <1> to <3>, wherein the n⁺-type diffusion layer has a sheet resistance of from 20Ω/□ to 60Ω/□.

<5> The photovoltaic cell substrate according to any one of <1> to <4>, wherein the n-type diffusion layer comprises a region having an n-type impurity concentration at a surface of from 10¹⁸ atoms/cm³ to 10²⁰ atoms/cm³, and has a junction depth of from 0.1 μm to 0.4 μm.

<6> The photovoltaic cell substrate according to any one of <1> to <5>, wherein the n⁺-type diffusion layer is obtained by applying, to a semiconductor substrate, a composition for forming an n-type diffusion layer that comprises a glass powder including an n-type impurity atom and a dispersing medium, and then sintering the composition for forming an n-type diffusion layer.

<7> The photovoltaic cell substrate according to <6>, wherein the n-type impurity atom is at least one selected from the group consisting of phosphorus and antimony.

<8> The photovoltaic cell substrate according to <6> or <7>, wherein the glass powder including an n-type impurity atom comprises at least one n-type impurity-containing substance selected from the group consisting of P₂O₃, P₂O₅ and Sb₂O₃; and at least one glass component selected from the group consisting of SiO₂, K₂O, Na₂O, Li₂O, BaO, SrO, CaO, MgO, BeO, ZnO, PbO, CdO, SnO, ZrO₂, TiO₂ and MoO₃.

<9> A method of producing the photovoltaic cell substrate according to any one of <1> to <8>, the method comprising a process of applying, to a semiconductor substrate, a composition for forming an n-type diffusion layer that comprises a glass powder including an n-type impurity atom and a dispersing medium, and a process of performing heat diffusion treatment of the semiconductor substrate to which the composition for forming an n-type diffusion layer has been applied.

<10> A photovoltaic cell element comprising the photovoltaic cell substrate according to any one of <1> to <8> and an electrode formed on the n⁺-type diffusion layer of the photovoltaic cell substrate.

<11> A photovoltaic cell comprising the photovoltaic cell element according to <10> and a wiring material disposed on the electrode of the photovoltaic cell element.

### Effect of the Invention

According to the invention, it is possible to provide a photovoltaic cell substrate in which mislocation of an electrode with respect to an n⁺-type diffusion layer that has a high n-type impurity concentration and is positioned right under the electrode, in a photovoltaic cell having a selective emitter structure. It is also possible to provide a method of producing a photovoltaic cell substrate, a photovoltaic cell element and a photovoltaic cell.

### BRIEF DESCRIPTION OF THE DRAWINGS

FIG. 1 is an electron microscope photograph showing a texture structure of a semiconductor substrate on which concave portions are formed.

FIG. 2 is a magnified image of the electron microscope photograph of FIG. 1.

### EMBODIMENTS FOR IMPLEMENTING THE INVENTION

In the present specification, the term “process” refers not only to an independent process but also to a process that cannot be clearly distinguished from another process, insofar as the purpose of the process is achieved. Further, a numerical range expressed by “A to B” refers to a range that includes A and B as the minimum value and the maximum value, respectively.

<Photovoltaic Cell Substrate>

The photovoltaic cell substrate is a semiconductor substrate having an n-type diffusion layer, an n⁺-type diffusion layer having a higher n-type impurity concentration than the n-type diffusion layer, and a concave portion at a surface of the n⁺-type diffusion layer.

The n⁺-type diffusion layer is provided in a region on which a light-receiving surface electrode of a photovoltaic cell is to be formed. By forming an n⁺-type diffusion layer, collection of carriers generated can be performed efficiently. Therefore, the n⁺-type diffusion layer is preferably formed in the shape that corresponds to the shape of the position for the light-receiving surface electrode.

On the other hand, an n-type diffusion layer, which has a lower n-type impurity concentration than that of the n⁺-type diffusion layer, is formed in a region that is to be a light-receiving surface on which a light-receiving surface electrode is not formed. Since the n-type impurity concentration of the n-type diffusion layer is lower than that of the n⁺-type diffusion layer, light at a shorter wavelength can be utilized efficiently, and the recombination loss of generated carriers can be suppressed.

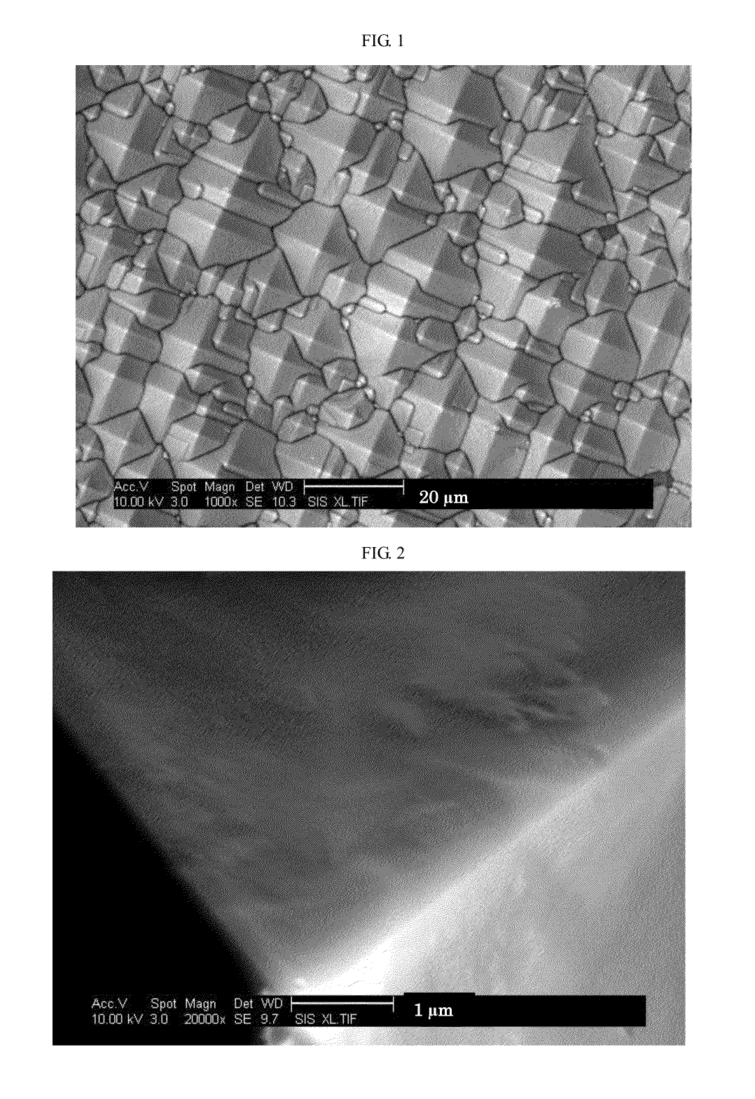

The surface of the n⁺-type diffusion layer has a concave portion. Therefore, the n⁺-type diffusion layer can be distinguished from the neighboring regions. Accordingly, alignment of a region in which the n⁺-type diffusion layer is formed and an electrode can be performed with high accuracy. FIG. 1 is an electron microscope photograph showing an example of a texture structure on which concave portions are formed. As shown in a magnified photograph of FIG. 2, concave portions are formed on the texture structure.

The n⁺-type diffusion layer having a concave portion on its surface is obtained by applying, to a semiconductor substrate, a composition for forming an n-type diffusion layer that includes a glass powder including an n-type impurity atom (hereinafter, also simply referred to as a glass powder) and a dispersing medium, and sintering the same. During sintering, a glass component included in the composition for forming an n-type diffusion layer, which is in contact with the semiconductor substrate, locally reacts with the semiconductor substrate to form an amorphous portion. It is considered that a concave portion is formed on the surface of the n⁺-type diffusion layer after dissolving the amorphous portion with hydrofluoric acid.

In the following, the composition for forming an n-type diffusion layer will be described. Subsequently, the method of producing a photovoltaic cell substrate with the composition for forming an n-type diffusion layer will be described.

(Composition for Forming n-Type Diffusion Layer)

The composition for forming an n-type diffusion layer includes a glass powder that includes an n-type impurity atom, and a dispersing medium. The composition for forming an n-type diffusion layer may include other additives, in consideration of coatability or the like.

The composition for forming an n-type diffusion layer refers to a material that includes an n-type impurity atom, and is capable of forming an n-type diffusion layer when it is applied onto a semiconductor substrate and subjected to a heat diffusion treatment by which the n-type impurity is thermally diffused into the semiconductor substrate.

By using a composition for forming an n-type diffusion layer that includes an n-type impurity atom in a glass powder, an n⁺-type diffusion layer can be formed at a desired portion without forming unnecessary n⁺-type diffusion layers on the back side or the edge side of the semiconductor substrate. It is considered that since the n-type impurity atom is bound to elements in the glass powder or taken in the glass, the n-type impurity in the glass powder tends not to volatilize even during sintering, whereby formation of an n-type diffusion layer not only on the front surface but also on the back surface or the edges, which may be caused by generation of a volatilized gas, is suppressed

The n-type impurity atom included in the glass powder is an element that can form an n-type diffusion layer by diffusing into a semiconductor substrate. Examples of the n-type impurity atoms include elements of Group 15 that include phosphorus (P), antimony (Sb), bismuth (Bi) and arsenic (As). From the viewpoint of safety and ease of including in glass, phosphorus or antimony is preferred.

The n-type impurity atom is preferably used as a substance including an n-type impurity that can be introduced into a glass powder. Examples of the substance including an n-type impurity include P₂O₃, P₂O₅, Sb₂O₃ and AsO₃. Among these, at least one selected from the group consisting of P₂O₃, P₂O₅ and Sb₂O₃ is preferred.

The melting temperature, the softening temperature, the glass transition temperature, the chemical durability or the like of the glass powder can be controlled by adjusting the component ratio, as necessary. Further, the glass powder preferably includes a glass component substance as described below.

Examples of the glass component substance include SiO₂, K₂O, Na₂O, Li₂O, BaO, SrO, CaO, MgO, BeO, ZnO, PbO, CdO, SnO, ZrO₂, MoO₃, La₂O₃, Nb₂O₅, Ta₂O₅, Y₂O₃, TiO₂, ZrO₂, GeO₂, TeO₂, Lu₂O₃ and V₂O₅. Among these, at least one selected from the group consisting of SiO₂, K₂O, Na₂O, Li₂O, BaO, SrO, CaO, MgO, BeO, ZnO, PbO, CdO, SnO, ZrO₂, TiO₂ and MoO₃ is preferred.

Specific examples of the glass powder including an n-type impurity atom include a system that include the substance including an n-type impurity as mentioned above and the glass component substance.

Specific examples include a glass powder of a system that includes P₂O₅ as a substance including an n-type impurity, such as a P₂O₅—SiO₂ system (described in the order of substance including n-type impurity-glass component substance, hereinafter the same shall apply), a P₂O₅—K₂O system, a P₂O₅—Na₂O system, a P₂O₅—Li₂O system, a P₂O₅—BaO system, a P₂O₅—SrO system, a P₂O₅—CaO system, a P₂O₅—MgO system, a P₂O₅—BeO system, a P₂O₅—ZnO system, a P₂O₅—CdO system, a P₂O₅—PbO system, a P₂O₅—V₂O₅ system, a P₂O₅—SnO system, a P₂O₅—GeO₂ system and a P₂O₅—TeO₂ system; and systems as described above in which the substance including an n-type impurity is Sb₂O₃ instead of P₂O₅.

It is also possible to use a glass powder including two or more kinds of substances including an n-type impurity, such as a P₂O₅—Sb₂O₃ system and a P₂O₅—As₂O₃ system.

The examples as mentioned above are composed of two components. However, a glass powder composed of three components, including two or more glass component substances such as P₂O₅—SiO₂—V₂O₅ and P₂O₅—SiO₂—CaO, is also applicable.

The content ratio of the glass component substance in the glass powder is preferably adjusted in consideration of its melting temperature, softening temperature, glass transition temperature, chemical durability or the like. Typically, the content of the glass component substance in the glass powder is preferably from 0.1 mass % to 95 mass %, more preferably from 0.5 mass % to 90 mass %.

More specifically, in a case of a glass of P₂O₅—SiO₂—CaO system, the content of CaO is preferably from 1 mass % to 30 mass %, more preferably from 5 mass % to 20 mass %.

The softening temperature of the glass powder is preferably from 200° C. to 1000° C., more preferably from 300° C. to 900° C., from the viewpoint of diffusability or suppressing dripping during the diffusion treatment.

The shape of the glass powder may be, for example, hemispherical, flat, blocky, platy or scaly. From the viewpoint of coatability to a substrate when it is applied as a composition for forming an n-type diffusion layer or performing uniform diffusion, the glass powder preferably has a flat shape or a platy shape.

The particle size of the glass powder is preferably 100 μm or less. In a case in which a glass powder having a particle size of 100 μm or less is used, a smooth coating tends to be obtained. The particle size of the glass powder is more preferably 50 μm or less, further preferably 10 μm or less. The lower limit of the particle size of the glass powder is not specifically limited, but the particle size is preferably 0.01 μm or more.

The particle size of the glass refers to an average particle size, and can be measured with a particle size distribution analyzer in accordance with a laser scattering diffraction method.

The glass powder including an n-type impurity atom may be prepared in accordance with the following process.

First, the starting materials, for example, a substance including an n-type impurity and a glass component substance are weighed and placed in a crucible. The material for the crucible may be platinum, platinum-rhodium, iridium, alumina, quartz, carbon or the like, and a suitable material may be selected in consideration of melting temperature, ambient, reactivity with a substance to be melted, and the like.

Subsequently, the starting materials are made into a melt by heating at a temperature according to the glass composition in an electric furnace. During heating, the melt is preferably stirred in order to be uniform.

Then, the obtained melt is made into a glass by casting onto a substrate of zirconia, carbon or the like.

Finally, the obtained glass is made into a powder by pulverization. A known apparatus such as a jet mill, a bead mill or a ball mill can be used for the pulverization.

The content of the glass powder including an n-type impurity atom in the composition for forming an n-type diffusion layer is determined in consideration of coatability, diffusability of the n-type impurity atom, and the like. Typically, the content of the glass powder in the composition for forming an n-type diffusion layer is preferably from 0.1 mass % to 95 mass %, more preferably from 1 mass % to 90 mass %.

The content of the substance including n-type impurity in the composition for forming an n-type diffusion layer is preferably from 5 mass % to 30 mass %, more preferably from 10 mass % to 20 mass %, from the viewpoint of achieving uniform diffusion of the n-type impurity atom and removability of a glass layer.

In the following, a dispersing medium is explained.

The dispersing medium is a medium for dispersing the glass powder in the composition for forming an n-type diffusion layer. Specific examples of the dispersing medium include a binder, a solvent, and a combination of a binder and a solvent.

—Binder—

Examples of the binder include polyvinyl alcohol, polyacrylamide resin, polyvinylamide resin, polyvinyl pyrrolidone, polyethylene oxide resin, polysulfonic acid, acrylamide alkylsulfonic acid, cellulose ether resin, cellulose derivatives, carboxymethyl cellulose, hydroxyethyl cellulose, ethyl cellulose, gelatin, starch and starch derivatives, sodium alginate and sodium alginate derivatives, xanthan and xanthan derivatives, guar and guar derivatives, scleroglucan and scleroglucan derivatives, tragacanth and tragacanth derivatives, dextrin and dextrin derivatives, (meth)acrylic acid resin, (meth)acrylic acid ester resin (such as alkyl (meth)acrylate resin and dimethylaminoethyl (meth)acrylate resin), butadiene resin, styrene resin, and copolymers of these resins. Further, siloxane resin may be suitably used. The binder may be used alone or in a combination of two or more kinds.

The molecular weight of the binder is not specifically limited, and may be adjusted appropriately in view of the desired viscosity of the composition. From the viewpoint of solubility in a solvent and handleability of the solution, the weight-average-molecular weight of the binder is preferably from 5,000 to 500,000, more preferably from 10,000 to 200,000, further preferably from 20,000 to 100,000.

—Solvent—

Examples of the solvent include ketone solvents such as acetone, methyl ethyl ketone, methyl-n-propyl ketone, methyl-iso-propyl ketone, methyl-n-butyl ketone, methyl-iso-butyl ketone, methyl-n-pentyl ketone, methyl-n-hexyl ketone, diethyl ketone, dipropyl ketone, di-iso-butyl ketone, trimethyl nonanone, cyclohexanone, cyclopentanone, methyl cyclohexanone, 2,4-pentandione and acetonyl acetone; ether solvents such as diethyl ether, methyl ethyl ether, methyl-n-propyl ether, di-iso-propyl ether, tetrahydrofuran, methyl tetrahydrofuran, dioxane, dimethyl dioxane, ethylene glycol dimethyl ether, ethylene glycol diethyl ether, ethylene glycol di-n-propyl ether, ethylene glycol dibutyl ether, diethylene glycol dimethyl ether, diethylene glycol diethyl ether, diethylene glycol methyl ether ether, diethylene glycol methyl-n-propyl ether, diethylene glycol methyl-n-butyl ether, diethylene glycol di-n-propyl ether, diethylene glycol di-n-butyl ether, diethylene glycol methyl-n-hexyl ether, triethylene glycol dimethyl ether, triethylene glycol diethyl ether, triethylene glycol methyl ethyl ether, triethylene glycol methyl-n-butyl ether, triethylene glycol di-n-butyl ether, triethylene glycol methyl-n-hexyl ether, tetraethylene glycol dimethyl ether, tetraethylene glycol diethyl ether, tetradiethylene glycol methyl ethyl ether, tetraethylene glycol methyl-n-butyl ether, diethylene glycol di-n-butyl ether, tetraethylene glycol methyl-n-hexyl ether, tetraethylene glycol di-n-butyl ether, propylene glycol dimethyl ether, propylene glycol diethyl ether, propylene glycol di-n-propyl ether, propylene glycol dibutyl ether, dipropylene glycol dimethyl ether, dipropylene glycol diethyl ether, dipropylene glycol methyl ethyl ether, dipropylene glycol methyl-n-butyl ether, dipropylene glycol di-n-propyl ether, dipropylene glycol di-n-butyl ether, dipropylene glycol methyl-n-hexyl ether, tripropylene glycol dimethyl ether, tripropylene glycol diethyl ether, tripropylene glycol methyl ethyl ether, tripropylene glycol methyl-n-butyl ether, tripropylene glycol di-n-butyl ether, tripropylene glycol methyl-n-hexyl ether, tetrapropylene glycol dimethyl ether, tetrapropylene glycol diethyl ether, tetradipropylene glycol methyl ethyl ether, tetrapropylene glycol methyl-n-butyl ether, dipropylene glycol di-n-butyl ether, tetrapropylene glycol methyl-n-hexyl ether and tetrapropylene glycol di-n-butyl ether;

ester solvents such as methyl acetate, ethyl acetate, n-propyl acetate, i-propyl acetate, n-butyl acetate, i-butyl acetate, sec-butyl acetate, n-pentyl acetate, sec-pentyl acetate, 3-methoxybutyl acetate, methyl pentyl acetate, 2-ethyl butyl acetate, 2-ethyl hexyl acetate, 2-(2-butoxyethoxy)acetate, benzyl acetate, cyclohexyl acetate, methyl cyclohexyl acetate, nonyl acetate, methyl acetoacetate, ethyl acetoacetate, diethylene glycol methyl ether acetate, diethylene glycol monoethyl ether acetate, dipropylene glycol methyl ether acetate, dipropylene glycol ethyl ether acetate, glycol diacetate, methoxy triglycol acetate, ethyl propionate, n-butyl propionate, i-amyl propionate, diethyl oxalate, di-n-butyl oxalate, methyl lactate, ethyl lactate, n-butyl lactate, n-amyl lactate, ethylene glycol methyl ether propionate, ethylene glycol ethyl ether propionate, ethylene glycol methyl ether acetate, ethylene glycol ethyl ether acetate, propylene glycol methyl ether acetate, propylene glycol ethyl ether acetate, propylene glycol propyl ether acetate, γ-buthylolactone and γ-valerolactone;

aprotic polar solvents such as acetonitrile, N-methylpyrrolidinone, N-ethyl pyrrolidinone, N-propyl pyrrolidinone, N-butyl pyrrolidinone, N-hexyl pyrrolidinone, N-cyclohexyl pyrrolidinone, N,N-dimethyl formamide, N,N-dimethylacetamide and dimethyl sulfoxide; alcohol solvents such as methanol, ethanol, n-propanol, i-propanol, n-butanol, i-butanol, sec-butanol, t-butanol, n-pentanol, i-pentanol, 2-methyl butanol, sec-pentanol, t-pentanol, 3-methoxybutanol, n-hexanol, 2-methyl pentanol, sec-hexanol, 2-ethyl butanol, sec-heptanol, n-octanol, 2-ethyl hexanol, sec-octanol, n-nonyl alcohol, n-decanol, sec-undecyl alcohol, trimethyl nonyl alcohol, sec-tetradecyl alcohol, sec-heptadecyl alcohol, phenol, cyclohexanol, methyl cyclohexanol, benzyl alcohol, ethylene glycol, 1,2-propylene glycol, 1,3-butylene glycol, diethylene glycol, dipropylene glycol, triethylene glycol and tripropylene glycol;

glycol monoether solvents such as ethylene glycol monomethyl ether, ethylene glycol monoethyl ether, ethylene glycol monophenyl ether, diethylene glycol monomethyl ether, diethylene glycol monoethyl ether, diethylene glycol mono-n-butyl ether, diethylene glycol mono-n-hexyl ether, ethoxytriglycol, tetraethylene glycol mono-n-butyl ether, propylene glycol monomethyl ether, dipropylene glycol monomethyl ether, dipropylene glycol monoethyl ether and tripropylene glycol monomethyl ether; terpene solvents such as α-terpinene, α-terpinenol, myrcene, alloocimene, limonene, dipentene, α-pinene, β-pinene, terpineol, carvone, ocimene and phellandrene; and water. The solvent may be used alone or in a combination of two or more kinds.

By mixing the glass powder including an n-type impurity atom and a dispersing medium, a composition for forming an n-type diffusion layer can be obtained.

The content of the dispersing medium in the composition for forming an n-type diffusion layer is determined in consideration of application suitability with respect to a semiconductor substrate, n-type impurity concentration, and the like.

From the viewpoint of the application suitability with respect to a semiconductor substrate, the viscosity of the composition for forming an n-type diffusion layer is preferably from 10 mPa·s to 1,000,000 mPa·s, more preferably from 50 mPa·s to 500,000 mPa·s.

<Method of Producing Photovoltaic Cell Substrate>

In the following, a method of producing a photovoltaic cell substrate is explained, with reference to an example in which a silicon substrate is sued as the semiconductor substrate.

First, a damage layer formed on a silicon substrate is removed by etching with an acid or alkali solution.

Then, a protection film of silicon oxide or silicon nitride is formed on one surface of the silicon substrate. A silicon oxide film may be formed by, for example, an ordinary CVD method using a silane gas and oxygen. A silicon nitride film may be formed by, for example, a plasma CVD method using a silane gas, an ammonia gas and a nitrogen gas.

Subsequently, a structure having fine irregularities, also referred to as a texture structure, is formed on a surface of the silicon substrate on which the protection film is not formed. The texture structure may be formed by, for example, dipping the silicon substrate having the protection film in a solution including potassium hydroxide and isopropyl alcohol (IPA) of approximately 80° C.

Thereafter, the silicon substrate is dipped in hydrofluoric acid in order to remove the protection film by etching.

Next, on the surface of the silicon substrate on which the texture structure is formed, the composition for forming an n-type diffusion layer is applied in the form of the shape of a light-receiving electrode. The composition for forming an n-type diffusion layer may be applied in the form of, for example, a comb shape. The width of the shape of the applied composition for forming an n-type diffusion layer is preferably greater than the width of the electrode, and desirably appropriately adjusted in accordance with the design of the electrode or the like. Typically, the composition for forming an n-type diffusion layer is preferably applied so as to have a width that is greater than the electrode width by from 5 μm to 100 μm.

The method for applying the composition for forming an n-type diffusion layer is not specifically limited and may be selected from ordinary methods. Examples of the method include screen printing, gravure printing, spin coating, brush coating, spray coating, doctor blade coating, roll coating and ink jetting.

The application amount of the composition for forming an n-type diffusion layer is not specifically limited. For example, if the composition for forming an n-type diffusion layer is in the form of a glass paste, the amount of the glass powder (excluding a dispersing medium etc.) is preferably from 0.01 g/cm² to 100 g/cm², more preferably from 0.1 g/cm² to 10 g/cm².

After applying the composition for forming an n-type diffusion layer onto the silicon substrate, a heating process for removing at least part of the dispersing medium may be provided. By heating the silicon substrate on which the composition for forming an n-type diffusion layer has been applied at from 100° C. to 200° C. (specifically, for example, 150° C.) for example, at least part of the solvent can be evaporated. Alternatively, for example, at least part of a binder may be removed together with a solvent by heating at from 300° C. to 600° C. (specifically, for example, 450° C.).

Subsequently, by subjecting the silicon substrate on which the composition for forming an n-type diffusion layer has been applied to a heat treatment, an n⁺-type diffusion layer having a high n-type impurity concentration is formed. By carrying out the heat treatment, n-type impurity is diffused from the composition for forming an n-type diffusion layer into the silicon substrate, thereby forming an n⁺-type diffusion layer having a high n-type impurity concentration.

The temperature for the heat treatment is preferably from 800° C. to 1000° C., more preferably from 850° C. to 950° C., further preferably from 870° C. to 900° C.

The size (width) of the n⁺-type diffusion layer formed in the heat treatment is preferably greater than the size (width) of the electrode by from 5 μm to 100 μm, in consideration of mislocation that may occur during formation of the electrode on the n⁺-type diffusion layer. For example, when the width of the finger portion of the light-receiving electrode is 100 μm, the width of the n⁺-type diffusion layer under the finger portion is preferably from 105 μm to 200 μm.

Subsequently, an n-type diffusion layer, which has a lower n-type impurity concentration than the n⁺-type diffusion layer, is formed in a region other than the n⁺-type diffusion layer. The n-type diffusion layer is formed by applying a composition for forming an n-type diffusion layer having a lower n-type impurity concentration than the composition for forming an n-type diffusion layer used for forming the n⁺-type diffusion layer, or by subjecting the silicon substrate on which the n⁺-type diffusion layer has been formed to a heat treatment in an atmosphere including an n-type impurity.

In a case of forming an n-type diffusion layer by applying a composition for forming an n-type diffusion layer, a composition for forming an n-type diffusion layer having a lower n-type impurity concentration than the composition for forming an n-type diffusion layer used for forming the n⁺-type diffusion layer is used. By using two kinds of compositions for forming an n-type diffusion layer having different n-type impurity concentrations, it is possible to form an n⁺-type diffusion layer having a high n-type impurity concentration in a region on which an electrode is to be formed, and form an n-type diffusion layer having a low n-type impurity concentration in a region other than the n⁺-type diffusion layer (light-receiving region).

The method of forming an n-type diffusion layer by applying a composition for forming an n-type diffusion layer is not limited to the above method. For example, an n-type diffusion layer may be formed by applying a composition for forming an n-type diffusion layer having a low n-type impurity concentration to the entire surface of a silicon substrate after forming an n⁺-type diffusion layer on the silicon substrate in a patterned manner by applying a composition for forming an n-type diffusion layer having a high n-type impurity concentration. Alternatively, an n-type diffusion layer may be formed by applying a composition for forming an n-type diffusion layer having a low n-type impurity concentration to the entire surface of a silicon substrate before forming an n⁺-type diffusion layer on the silicon substrate in a patterned manner by applying a composition for forming an n-type diffusion layer having a high n-type impurity concentration.

In a case of forming an n-type diffusion layer by carrying out a heat treatment in an atmosphere including an n-type impurity, the atmosphere including an n-type impurity is not specifically limited as long as it includes an n-type impurity. Examples include an atmosphere of a mixed gas of phosphorous oxychloride (POCl₃), nitrogen and oxygen. The heating conditions may be the same as the heating conditions for forming the n⁺-type diffusion layer.

On the silicon substrate on which the n⁺-type diffusion layer and the n⁺-type diffusion layer have been formed, a glass layer remains due to the glass component in the composition used for forming the n⁺-type diffusion layer (and the composition used for forming the n-type diffusion layer, when the n-type diffusion layer is formed by applying a composition for forming an n-type diffusion layer). The glass layer is preferably removed. The method for removing the glass layer may be any known method such as dipping in an acid such as hydrofluoric acid, dipping in an alkali such as sodium hydroxide.

As described above, the glass component included in the composition for forming an n-type diffusion layer used for forming the n⁺-type diffusion layer locally reacts with the silicon substrate during sintering to form an amorphous portion. It is considered that a concave portion is formed on the surface of the n⁺-type diffusion layer as a result of dissolving the amorphous portion with an acid such as hydrofluoric acid. On the other hand, a concave portion is not formed on the surface of the n-type diffusion layer, or the size of the concave portion is extremely small. Therefore, the surface roughness of the n⁺-type diffusion layer is different from that of the n-type diffusion layer, whereby the region of the n⁺-type diffusion layer can be distinguished from the region of the n-type diffusion layer.

In a case of forming an n-type diffusion layer by applying a composition for forming an n-type diffusion layer, since the n-type impurity concentration of the composition for forming an n-type diffusion layer is low, the size of a concave portion formed on the n-type diffusion layer can be extremely small. Accordingly, the surface roughness of the light-receiving region, in which the n-type diffusion layer is formed, can be approximately zero, thereby not affecting the power generation performances of a photovoltaic cell.

<Properties of Photovoltaic Cell Substrate>

The n⁺-type diffusion layer of the photovoltaic cell substrate has a concave portion on its surface. Due to the existence of the concave portion, the center line average roughness Ra of the surface of the n⁺-type diffusion layer is preferably from 0.004 μm to 0.100 μm, more preferably from 0.007 μm to 0.080 μm, further preferably from 0.010 μm to 0.050 μm. When Ra is 0.100 μm or less, disappearance of a diffusion region having a high n⁺-type impurity concentration can be suppressed. When Ra is 0.004 μm or more, the n⁺-type diffusion layer can be distinguished more easily.

The center line average roughness Ra of the surface of the n⁺-type diffusion layer is a value as measured according to the method of JIS B 0601. However, the object for the measurement is positioned on a small triangle that forms a pyramid having a height of approximately 5 μm and a base of approximately 20 μm, which is a portion of an n⁺-type diffusion layer of a texture structure of the surface of a semiconductor substrate, as shown in FIG. 2. Therefore, the length for the evaluation is set to 5 μm. The cut-off value λc for removing a waving component is not particularly necessary. The length for the evaluation may be greater than 5 μm. In that case, irregularity of the texture structure of the surface of the n⁺-type diffusion layer needs to be removed by cut-off.

The center line average roughness Ra of the surface of the n⁺-type diffusion layer may be measured with a 3D laser scanning microscope (VK-9700, trade name, manufactured by Keyence Corporation, laser wavelength: 408 nm) with an object lens (magnification: 150, N.A.: 0.95 equivalent). Prior to the measurement, it is preferred to calibrate the measured value with a surface roughness scale (No. 178-605, manufactured by Mitutoyo Corporation).

It is also possible to measure the center line average roughness Ra of the surface of the n⁺-type diffusion layer as a roughness in a region (i.e., plane roughness) with a 3D laser scanning microscope (VK-9700, trade name, manufactured by Keyence Corporation, laser wavelength: 408 nm). Likewise, an object lens (magnification: 150, N.A.: 0.95 equivalent) may be used. In that case, prior to the measurement, it is necessary to calibrate the measured value with a surface roughness scale (No. 178-605, manufactured by Mitutoyo Corporation).

The n⁺-type diffusion layer preferably has a sheet resistance of from 20Ω/□ to 60Ω/□, more preferably from 30Ω/□ to 40Ω/□, from the viewpoint of lowering the contact resistance of the semiconductor substrate with respect to an electrode to be formed on the n⁺-type diffusion layer.

The sheet resistance is an arithmetic average of 25 values measured by a four probe method. The sheet resistance can be measured by, for example, with a low resistivity meter (LORESTA-EP MCP-T360, trade name, manufactured by Mitsubishi Chemical Analytech Co., Ltd.) at 25° C.

The n⁺-type diffusion layer may satisfy the center line average roughness Ra as specified above by having one concave portion, or by having plural concave portions. When there are plural concave portions, the concave portion may exist independently from each other or may exist in a consecutive manner.

The junction depth of the n⁺-type diffusion layer is preferably from 0.5 μm to 3.0 μm, more preferably from 0.5 μm to 2.0 μm. The junction depth of the n⁺-type diffusion layer can be measured by secondary ion mass spectrometry (SIMS) with a universal magnetic sector (IMS-7F, trade name, manufactured by CAMECA).

The n⁺-type diffusion layer preferably has a region in which the n-type impurity concentration of 10²⁰ atoms/cm³ or more in at least a portion of a range of from 0.10 μm to 1.00 μm in depth from the surface of the substrate, more preferably from 0.12 μm to 1.00 μm in depth from the surface of the substrate.

Generally, the diffusion concentration of the n-type impurity decreases from the surface toward the inside of the substrate. Therefore, when the relationship of the n-type impurity concentration and the depth as set forth above is satisfied, a favorable ohmic contact can be obtained with an electrode in a region with a sufficiently high n-type impurity concentration, even in a case in which the surface layer of the substrate is eroded due to a glass component included in the electrode.

The n-type impurity concentration in a depth direction can be measured by secondary ion mass spectrometry (SIMS) with a universal magnetic sector (IMS-7F, trade name, manufactured by CAMECA).

The n-type diffusion layer, having a lower n-type impurity concentration than the n⁺-type diffusion layer, preferably has a sheet resistance of from 80Ω/□ to 120Ω/□, more preferably from 90Ω/□ to 100Ω/□.

The n-type diffusion layer preferably has a region in which the n-type impurity concentration is from 10¹⁸ atoms/cm³ to 10²⁰ atoms/cm³ on the surface (at least a portion at a range of up to 0.025 μm in depth from the surface of the substrate), more preferably has a region in which the n-type impurity concentration is from 10¹⁹ atoms/cm³ to 5×10¹⁹ atoms/cm³ in at least a portion at a range of up to 0.025 μm in depth from the surface of the substrate.

The junction depth of the n-type diffusion layer is preferably from 0.1 μm to 0.4 μm, more preferably from 0.15 μm to 0.3 μm. By having the junction depth as specified above, recombination of carriers generated by light irradiation can be effectively suppressed, and collection of light at the n-type diffusion layer can be efficiently carried out. The junction depth of the n-type diffusion layer can be measured by secondary ion mass spectrometry (SIMS) with a universal magnetic sector (IMS-7F, trade name, manufactured by CAMECA).

By using a photovoltaic substrate having an n⁺-type diffusion layer with a concave portion formed on the surface thereof, alignment of an electrode can be carried out with high accuracy for applications in which an electrode is formed on a high-concentration impurity diffusion layer, not only for photovoltaic cells. Accordingly, the photovoltaic cell substrate may be used as a semiconductor substrate for purposes other than photovoltaic cells.

<Photovoltaic Cell Element and Method of Producing Photovoltaic Cell Element>

The photovoltaic cell element of the invention includes the photovoltaic cell substrate as described above and an electrode provided on the n⁺-type diffusion layer of the photovoltaic cell substrate. In the following, an exemplary method of producing the photovoltaic cell element will be described.

As previously explained, a photovoltaic cell substrate is obtained by removing a glass layer formed on an n⁺-type diffusion layer and an n-type diffusion layer formed on a semiconductor substrate. The surface of the photovoltaic cell substrate on which the n⁺-type diffusion layer and the n-type diffusion layer have been formed is used as a light-receiving surface.

An antireflection film may be formed on the light-receiving surface. The antireflection film may be, for example, formed of a nitride such as Si₃N₄ by a plasma CVD method.

Then, electrodes are formed on the back surface and the light-receiving surface of the photovoltaic cell substrate. The electrodes may be formed by an ordinary method without particular restriction.

For example, a light-receiving surface electrode (front surface electrode) may be formed by applying a metal paste for a front surface electrode, which includes metal particles and glass particles, onto a region to which an electrode is to be formed, and then sintering the metal paste.

During the process, the region on which the n⁺-type diffusion layer is formed is easily determined due to the presence of the concave portion on the surface of the n⁺-type diffusion layer, and the alignment of the electrode can be easily carried out. For example, the alignment can be carried out by mounting an alignment system controlled by a CCD camera to a screen printing machine.

The back surface electrode may be formed by, for example, applying a paste for a back surface electrode, which includes a metal such as aluminum, silver or copper, onto the back surface of the photovoltaic cell substrate, and then drying and sintering the same. For the purpose of connecting elements in the module process, a silver paste for forming a silver electrode may be provided at a portion of the back surface of the photovoltaic cell substrate.

<Photovoltaic Cell>

The photovoltaic cell of the invention includes the photovoltaic cell element, and a wiring material disposed on the electrode of the photovoltaic cell element. As necessary, the photovoltaic cell may have a structure in which plural photovoltaic cell elements are connected via a wiring material, and sealed with a sealing material.

The wiring material and the sealing material are not specifically restricted, and may be selected appropriately from the materials that are commonly used.

In the present specification, the photovoltaic cell element refers to a structure including a semiconductor substrate in which a pn junction is formed and an electrode formed on the semiconductor substrate. The photovoltaic cell refers to a structure including a photovoltaic cell element and a wiring material provided on an electrode of the photovoltaic cell element. As necessary, the photovoltaic cell may have a structure in which plural photovoltaic cell elements are connected via a wiring material, and sealed with a sealing material such as a resin.

### EXAMPLES

In the following, the invention will be described in further detail with reference to the Examples. However, the invention is not limited to the Examples. Unless otherwise specified, reagents were used as the chemical substances. The “%” and the “parts” are on the mass basis. The center line average roughness Ra, the sheet resistance, the n-type impurity concentration and the junction depth were measured with apparatuses as mentioned above.

### Example 1

### Preparation of Photovoltaic Cell Substrate

A composition for forming an n-type diffusion layer A was prepared by mixing 10 g of a glass powder (including P₂O₅, SiO₂ and CaO as main components at a ratio of 50%, 43% and 7%, respectively), 4 g of ethyl cellulose and 86 g of terpineol.

Subsequently, the composition for forming an n-type diffusion layer A was applied on a light-receiving surface with a texture structure of a p-type silicon substrate (manufactured by PVG Solutions, thickness: 180 μm) by screen printing in the form of an electrode including a finger portion (width: 150 μm) and a bus bar portion (width: 1.5 mm). The composition was dried at 150° C. for 10 minutes, and was subjected to a heat treatment at 350° C. for 3 minutes in order to remove the solvent and the binder. Then, the composition was subjected to a heat treatment in the atmosphere at 900° C. for 10 minutes, whereby an n-type impurity was diffused into the silicon substrate. An n⁺-type diffusion layer was thus formed on a region on which an electrode was to be formed.

The resultant was subjected to a heat treatment at 830° C. for 10 minutes in an atmosphere of mixed gas of phosphorus oxychloride (POCl₃), nitrogen and oxygen (mixed ratio: 19.8%, 75.8% and 4.4%), whereby an n-type impurity was diffused into the silicon substrate. An n-type diffusion layer was thus formed on a light-receiving region of the light-receiving surface (other than the region for forming an electrode). Subsequently, a glass layer remaining on the surface of the silicon substrate was removed with hydrofluoric acid. Plural concave portions were formed in a consecutive manner on the entire surface of the n⁺-type diffusion layer. The center line average roughness Ra of the n⁺-type diffusion layer was 0.05 μm.

The average value of the sheet resistance of the n⁺-type diffusion layer was 40Ω/□, and the average value of the sheet resistance of the n-type diffusion layer was 102Ω/□.

In the n⁺-type diffusion layer, a region having an n-type impurity concentration of 10²⁰ atoms/cm³ or more was formed at a range of 0.13 μm in depth from the surface of the substrate.

On the surface of the n-type diffusion layer, a region having an n-type impurity concentration of 10²⁰ atoms/cm³ was formed.

The junction depth of the n⁺-type diffusion layer was 0.5 μm, and the junction depth of the n-type diffusion layer was 0.2 μm.

(Preparation of Photovoltaic Cell Element)

An antireflection film of Si₃N₄ was formed on the light-receiving surface of the silicon substrate on which the n⁺-type diffusion layer and the n-type diffusion layer were formed, a front surface electrode was formed on the region on which the electrode was to be formed, and a back surface electrode was formed on the back surface of the substrate, by ordinary methods, respectively. In the front surface electrode, the width of a finger portion was 100 μm and the width of a bus bar portion was 1.1 mm, respectively. The front surface electrode was formed from a silver electrode paste (Ag paste 159A, trade name, manufactured by DuPont) and the back surface electrode was formed from an aluminum electrode paste (Al paste HYPER BSF, trade name, manufactured by PVG Solutions), respectively by screen printing.

When forming the front surface electrode, alignment of the front surface electrode and the n⁺-type diffusion layer was carried out with an alignment system controlled by a CCD camera. The position on which the front surface electrode was formed and the region of the n⁺-type diffusion layer were observed with a microscope. As a result, mislocation (i.e., the front surface electrode was formed on a region on which the n⁺-type diffusion layer was not formed) was not observed. Further, it was confirmed that the region in which the n⁺-type diffusion layer was formed was larger than the finger portion of the front surface electrode by approximately 25 μm at both edges (i.e., the region of the n⁺-type diffusion layer extended from both edges of the finger portion by approximately 25 μm, respectively).

(Evaluation of Conversion Efficiency)

The conversion efficiency of the photovoltaic cell element prepared in the above process was measured and evaluated.

Specifically, the measurement was carried out with a combination of a solar simulator (WXS-1555-10, trade name, manufactured by Wacom Electric Co., Ltd.) and a current-voltage (I-V) measurement apparatus (I-V CURVE TRACER MP-160, trade name, manufactured by Eko Instruments Co., Ltd.). The Eff (conversion efficiency), which indicates power generation performances as a photovoltaic cell, can be obtained by conducting the measurement based on DIS-C-8912 and JIS-C-8913.

As a result, the obtained photovoltaic cell element exhibited a conversion efficiency that was improved by 0.5% as compared with a photovoltaic cell element in which an n⁺-type diffusion layer was not formed (not having a selective emitter structure).

### Example 2

A photovoltaic cell substrate was prepared in a similar manner to Example 1, except that the heat treatment for forming an n⁺-type diffusion layer was carried out at 950° C. for 10 minutes. The average value of the sheet resistance of the n⁺-type diffusion layer was 30Ω/□, and the average value of the sheet resistance of the n-type diffusion layer was 102Ω/□, respectively.

Plural concave portions were formed in a consecutive manner on the entire surface of the n⁺-type diffusion layer. The center line average roughness Ra of the n⁺-type diffusion layer was 0.08 μm.

In the n⁺-type diffusion layer, a region having an n-type impurity concentration of 10²⁰ atoms/cm³ or more was formed at a range of 0.20 μm in depth from the surface of the substrate.

On the surface of the n-type diffusion layer, a region having an n-type impurity concentration of 10²⁰ atoms/cm³ was formed.

The junction depth of the n⁺-type diffusion layer was 0.7 μm, and the junction depth of the n-type diffusion layer was 0.2 μm.

A photovoltaic cell element was prepared in a similar manner to Example 1, using the silicon substrate on which the n⁺-type diffusion layer and the n-type diffusion layer were formed in the above process. The position on which the front surface electrode was formed and the region of the n⁺-type diffusion layer were observed with a microscope. As a result, mislocation was not observed. Further, it was confirmed that the region in which the n⁺-type diffusion layer was formed was larger than the finger portion of the front surface electrode by approximately 25 μm at both edges of the front surface electrode.

The obtained photovoltaic cell element exhibited a conversion efficiency that was improved by 0.6% as compared with a photovoltaic cell element in which an n⁺-type diffusion layer was not formed (not having a selective emitter structure).

### Comparative Example 1

A photovoltaic cell substrate was prepared in a similar manner to Example 1, except that an n⁺-type diffusion layer was formed by using a diffusion solution including ammonium phosphate and carrying out the heat treatment at 900° C. for 10 minutes. The average value of the sheet resistance of the n⁺-type diffusion layer was 40Ω/□, and the average value of the sheet resistance of the n-type diffusion layer was 102Ω/□, respectively. No concave portion was observed on the surface of the n⁺-type diffusion layer. As a result, it was difficult to distinguish the region in which the n⁺-type diffusion layer was formed and the region in which the n-type diffusion layer was formed.

A photovoltaic cell element was prepared in a similar manner to Example 1, by using the silicon substrate in which the n⁺-type diffusion layer and the n-type diffusion layer were formed. It was confirmed with a microscope that there was a portion in which the position of the electrode formed on the light-receiving surface did not correspond to the n⁺-type diffusion layer.

The conversion efficiency of the obtained photovoltaic cell element was not improved as compared with a photovoltaic cell element in which an n⁺-type diffusion layer was not formed (not having a selective emitter structure). Further, it was confirmed that a fill factor, which is attributable to contact resistance, was significantly low. It is considered to be because there was mislocation between the region in which the n⁺-type diffusion layer was formed and the position of the electrode formed thereon, whereby the electrode was in contact with the n-type diffusion layer.

This application claims priority under 35 USC 119 from Japanese Patent Application No. 2011-162610 filed Jul. 25, 2011, the disclosure of which is incorporated by reference herein.

All publications, patent applications, and technical standards mentioned in this specification are herein incorporated by reference to the same extent as if each individual publication, patent application, or technical standard was specifically and individually indicated to be incorporated by reference.

What is claimed is:

1. A photovoltaic cell substrate that is a semiconductor substrate comprising an n-type diffusion layer, an n⁺-type diffusion layer having a higher n-type impurity concentration than the n-type diffusion layer, and a concave portion at a surface of the n⁺-type diffusion layer.

2. The photovoltaic cell substrate according to claim 1, wherein the surface of the n⁺-type diffusion layer has a center line average roughness Ra of from 0.004 μm to 0.100 μm.

3. The photovoltaic cell substrate according to claim 1, wherein the n⁺-type diffusion layer comprises a region having an n-type impurity concentration of from 10²⁰ atoms/cm³ or more in at least a portion at a range of from 0.10 μm to 1.00 μm in depth from the surface of the n⁺-type diffusion layer.

4. The photovoltaic cell substrate according to claim 1, wherein the n⁺-type diffusion layer has a sheet resistance of from 20Ω/□ to 60Ω/□.

5. The photovoltaic cell substrate according to claim 1, wherein the n-type diffusion layer comprises a region having an n-type impurity concentration of from 10¹⁸ atoms/cm³ to 10²⁰ atoms/cm³ at a surface of the n-type diffusion layer, and has a junction depth of from 0.1 μm to 0.4 μm.

6. The photovoltaic cell substrate according to claim 1, wherein the n⁺-type diffusion layer is obtained by applying, to a semiconductor substrate, a composition for forming an n-type diffusion layer that comprises a glass powder including an n-type impurity atom and a dispersing medium, and then sintering the composition for forming an n-type diffusion layer.

7. The photovoltaic cell substrate according to claim 6, wherein the n-type impurity atom is at least one selected from the group consisting of phosphorus and antimony.

8. The photovoltaic cell substrate according to claim 6, wherein the glass powder including an n-type impurity atom comprises at least one n-type impurity-containing substance selected from the group consisting of P₂O₃, P₂O₅ and Sb₂O₃; and at least one glass component substance selected from the group consisting of SiO₂, K₂O, Na₂O, Li₂O, BaO, SrO, CaO, MgO, BeO, ZnO, PbO, CdO, SnO, ZrO₂, TiO₂ and MoO₃.

9. A method of producing the photovoltaic cell substrate according to claim 1, the method comprising a process of applying, to a semiconductor substrate, a composition for forming an n-type diffusion layer that comprises a glass powder including an n-type impurity atom and a dispersing medium, and a process of performing heat diffusion treatment of the semiconductor substrate to which the composition for forming an n-type diffusion layer has been applied.

10. A photovoltaic cell element comprising the photovoltaic cell substrate according to claim 1 and an electrode formed on the n⁺-type diffusion layer of the photovoltaic cell substrate.

11. A photovoltaic cell comprising the photovoltaic cell element according to claim 10 and a wiring material disposed on the electrode of the photovoltaic cell element.
